(19) United States
(12) Patent Application Publication
(10) Pub. No.: US 2026/0118944 A1
(43) Pub. Date: Apr. 30, 2026

(54) SEMICONDUCTOR DEVICE

(71) Applicant: Nuvoton Technology Corporation, Hsinchu Science Park (TW)

(72) Inventor: Yung-Chi LAN, Taichung City (TW)

(21) Appl. No.: 19/090,621

(22) Filed: Mar. 26, 2025

(30) Foreign Application Priority Data
Oct. 28, 2024 (TW) 113140950

(51) Int. Cl. G06F 1/3287; G06F 1/3237; G06F 1/3246

(52) U.S. Cl. CPC G06F 1/3287; G06F 1/3237; G06F 1/3246

(57) ABSTRACT

The present invention provides a semiconductor device having two independent power domains: a first power domain and a second power domain. Different clock signals are applied to the respective circuits which are provided in the first and second power domains. The first and second power domains have a first storage unit and a second storage unit, respectively. When the semiconductor device enters a power-saving mode, the parameter of the first storage unit is maintained in the second storage unit, and then the first power domain is turned off. In the power-saving mode, the timing of each device in the second power domain is driven by the second clock signal, so as to solve the problem of clock domain crossing between different power domains. Therefore, the second power domain may use a second storage unit with a lower processing speed than the first storage unit.

### CROSS REFERENCE TO RELATED APPLICATIONS

This application claims priority of Taiwan Patent Application No. 113140950, filed on Oct. 28, 2024, the entirety of which is incorporated by reference herein.

### BACKGROUND OF THE INVENTION

### Field of the Invention

The present invention relates to a semiconductor device, and, in particular, it relates to a semiconductor device capable of keeping the setting value of a register in a power-saving mode.

### Description of the Related Art

In recent years, the technology trend of semiconductor products has continued to develop towards more advanced fabricating processes. The advantage is that more circuits can be arranged on a limited wafer region, but the accompanying disadvantage is that the higher the process level, the greater the leakage current of the circuit or component in the semiconductor product, thereby resulting in additional power consumption. In order to solve this power consumption problem, when a semiconductor device or system enters a power-saving mode, some unused circuit regions are powered off, to effectively prevent the consumption due to leakage current. However, the region in the semiconductor device that is powered off may contain registers that have stored settings, values or parameters, and the settings of these registers may be used to control the circuits in the region which is not powered off. Therefore, in a conventional design, it is necessary to retain these settings and parameters in the region where the power is not turned off, so that the circuits in the region where the power is not turned off can also operate according to the user's setting values in the power-saving mode.

However, for conventional circuit designs, the circuit in the non-powered off region for retaining the setting values still can be improved to be smaller and more power-saving. In addition, it is also desirable that when the semiconductor device leaves the power-saving mode, the setting values stored in the region that is not powered off can be restored to the region that was previously powered off.

### BRIEF SUMMARY OF THE INVENTION

Accordingly, the present invention provides a novel semiconductor device, which allows the circuit that stores the setting value in the non-powered-off region to be smaller and more power-saving. In addition, after the semiconductor device leaves the power-saving mode, the setting values stored in the region that is not powered off can be restored to the region that was previously powered off.

A semiconductor device according to one embodiment of the present invention, comprises: a first block circuit, and a second block circuit. The first circuit block is configured to operate according to a first clock signal and at least have a first power domain and a first storage unit. The second circuit block is configured to at least have a second power domain and a second storage unit. The input terminal of the second storage unit is coupled to the output terminal of the first storage unit. When the semiconductor device enters a power-saving mode, it performs an enter procedure, in which: the first circuit block stops outputting the first clock signal; the second circuit block then outputs a second clock signal and a save enable signal which are coupled to the second storage unit; the second storage unit stores the content of the first storage unit according to the save enable signal; and the semiconductor device powers off the first power domain.

In some embodiments of the present invention, the second circuit block further comprises a logic OR gate. One terminal of the logic OR gate is coupled to the input terminal of the second storage unit, and the other terminal of the logic OR gate is coupled to the output terminal of the first storage unit.

In some embodiments of the present invention, the second circuit block further comprises a clock gate cell. The input terminals of the clock gate cell receive the second clock signal and the save enable signal, and an output terminal of the clock gate cell is coupled to a clock input terminal of the second storage unit. When the storage signal is at a first logic level, the clock gate cell outputs the second clock signal, causing the second storage unit to store the content of the first storage unit.

In some embodiments of the present invention, the semiconductor device further comprises an isolation unit. The isolation unit is controlled by an isolation signal and is coupled to the output terminal of the first storage unit and the input terminal of the second storage unit. After the second storage unit has stored the content of the first storage unit, the second circuit block changes the isolation signal from a first logic level to a second logic level, such that the isolation unit restricts the output of the first storage unit to the second logic level to equivalently block the output of the first storage unit.

In some embodiments of the present invention, the isolation unit is a logic AND gate, which has one terminal coupled to the isolation signal, and the other terminal coupled to the output terminal of the first storage unit. The first logic level is a logic high level, and the second logic level is a logic low level. In addition, the clock gate cell may be an AND gate, and the first logic level is a logic high level. Furthermore, the first storage unit and the second storage unit may be flip-flops or latch circuits.

In some embodiments of the present invention, the first circuit block further comprises a first multiplexer and a second multiplexer. A first input terminal of the first multiplexer is coupled to the output terminal of the logic OR gate, a second input terminal of the first multiplexer receives data, and an output terminal of the first multiplexer is coupled to the input terminal of the first storage unit. A first input terminal of the second multiplexer receives a restore signal, a second input terminal of the second multiplexer receives the first clock signal, and an output terminal of the second multiplexer is coupled to the clock input terminal of the first storage unit. The control terminals of the first multiplexer and the second multiplexer are coupled to a selection signal.

In some embodiments of the present invention, when the semiconductor device leaves the power-saving mode, it performs a leave procedure that includes the following steps: (a) the semiconductor device restores power to the first power domain; (b) the second circuit block sets the selection signal to the first logic level, causing the first multiplexer and the second multiplexer to select their respective first input terminals as outputs; (c) The second circuit block outputs the restore signal, which is input to the input clock terminal of the first storage unit through the second multiplexer, causing the first storage unit to store the content of the second storage unit; and (d) the second circuit block changes the logic level of the selection signal from the first logic level to the second logic level, causing the first multiplexer and the second multiplexer to select their respective second input terminal as outputs.

In some embodiments of the present invention, during the leave procedure, after the first storage unit has stored the content of the second storage unit, the leave procedure further includes the following steps. The second circuit block resets the second storage unit; the second circuit block stops outputting the second clock signal; and the first circuit block outputs the first clock signal again.

In some embodiments of the present invention, when the semiconductor device leaves the power-saving mode, it performs a leave procedure that includes the following steps: the semiconductor restores power to the first power domain; the second circuit block changes the isolation signal from the second logic level to the first logic level, thereby releasing the blocking of the output of the first storage unit by the isolation unit; and the second circuit block resets the second storage unit.

In some embodiments of the present invention, the frequency of the second clock signal is lower than the frequency of the first clock signal.

### BRIEF DESCRIPTION OF THE DRAWINGS

The present invention can be more fully understood by reading the subsequent detailed description and examples with references made to the accompanying drawings, wherein:

FIG. 1 is a schematic diagram of a semiconductor device having a signal retain circuit.

FIG. 2 is an operation timing chart of the semiconductor device of FIG. 1 when it enters a power-saving mode.

FIG. 3 is a diagram showing a structure in which a plurality of buffers are provided in the semiconductor device of FIG. 1.

FIG. 4 is a structural diagram of a semiconductor device having a signal retain circuit according to one embodiment of the present invention.

FIG. 5 is an operation timing chart of the semiconductor device of FIG. 4 when it enters a power-saving mode.

FIG. 6 is an operation timing chart of the semiconductor device of FIG. 4 when it leaves the power-saving mode.

FIG. 7 is a structural diagram of a semiconductor device having a signal retain circuit and a signal restore circuit according to another embodiment of the present invention.

FIG. 8 is an example of an operation timing chart of the semiconductor device of FIG. 7 when it leaves the power-saving mode.

FIG. 9 is another example of an operation timing chart when the semiconductor device of FIG. 7 leaves the power-saving mode.

### DETAILED DESCRIPTION OF THE INVENTION

In order to make the aforementioned objects, features and advantages of the present invention more obvious and easier to understand, the following is a detailed description of preferred embodiments with reference to the accompanying drawings.

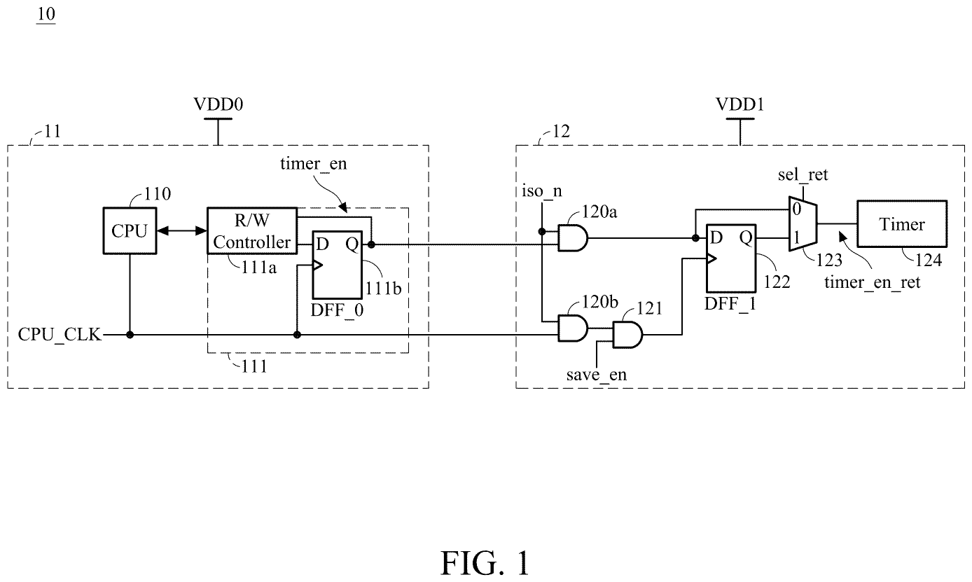

FIG. 1 is a schematic diagram of a semiconductor device having a signal retain circuit. In FIG. 1, the semiconductor device 10 includes a first circuit block 11 and a second circuit block 12. The first circuit block 11 has a first power domain and the second circuit block has a second power domain. That is, the power supply division on the semiconductor device 10 is at least arranged as the first power domain supplying power to the whole of part of the first circuit block 11, and the second power domain supplying power to the whole or part of the second circuit block 12. Hereinafter, the first power domain and the second power domain are labeled as VDD0 and VDD1, respectively.

Referring to FIG. 1, the first circuit block 11 includes a processor 110 and, for example but not limited to, a register controller 111 composed of at least a read/write controller (R/W controller) 111a and a storage unit 111b. The storage unit 111b may be a flip-flop or a latch of various types; here, for example, it is a D-type flip-flop (DFF_0). The processor 110 may be a central processing unit (CPU), a digital signal processor (DSP), a micro control unit (MCU), an arithmetic logic unit (ALU), or other devices or circuits with program execution and computing capabilities. The processor 110 operates by receiving the CPU clock signal CPU_CLK generated by the first circuit block 11. The storage unit 111b receives the output of the read/write controller 111a and the CPU clock signal CPU_CLK, to store signals or data.

Referring to FIG. 1, the second circuit block 12, that is the signal retain circuit, includes isolation units 120a and 120b, an AND gate (or a clock gating cell) 121, a storage unit 122, a multiplexer 123, and a timer 124. Here, the storage unit 122 may be a flip-flop or a latch of various types. Here, the storage unit 122, for example, is a D-type flip-flop (DFF_1), and the isolation units 120a and 120b are AND gates.

The semiconductor device 10 of FIG. 1 is, for example but not limited to, a device having a wake-up function of timer. The processor 110 can read and write the storage unit (DFF_0) 111b through the read/write controller 111a, and the setting value or the represented logic state stored by the storage unit 111b can be used to perform specific control and operation. In this example, it is used to control whether to enable the timer 124. In this example, if the semiconductor device 10 enters a power-saving mode, the semiconductor device 10 will cut off the power supply of the first power domain VDD0, while the power supply of the second power domain VDD1 is still maintained, so that the timer 124 can be operated in the power-saving mode. However, the timer 124 does not need to be operated every time the semiconductor device 10 enters the power-saving mode, so the user can modify the setting value of the storage unit (DFF_0) 111b to determine whether to enable the timer 124 in the power-saving mode. Therefore, the state of the storage (DFF_0) 111b must be retained in the power-saving mode so as to control whether to enable the timer 124 in the power-saving mode.

Here, the register controller 111 is arranged in the first power domain VDD0. When the semiconductor device 10 enters the power-saving mode, since the first power domain VDD0 is cut off power, the register controller 111 and the storage unit (DFF_0) 111b will be powered off. If the timer 124 in the second circuit block 12 needs to be controlled by the storage unit (DFF_0) 111b in the power-saving mode, the setting value of the storage unit (DFF_0) 111b must be transferred to the second circuit block 12 under the second power domain VDD1. In this example, the storage unit (DFF_1) 122 of the second circuit block 12 is arranged in the second power domain VDD1 for the purpose of storing the setting value of the storage unit (DFF_0) 111b and then providing it to the timer 124.

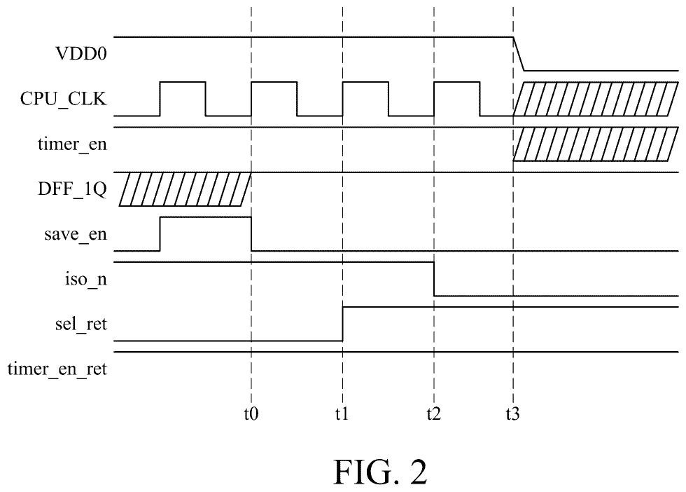

FIG. 2 is an operation timing chart of the semiconductor device 10 of FIG. 1 when it enters the power-saving mode. Referring to FIG. 1 and FIG. 2, at time to, since the isolation signal iso_n is at a logic high level, the signal timer_en, that is the setting value of the storage unit (DFF_0) 111b, can be coupled to the storage unit (DFF_1) 122 and one terminal (the “0” terminal) of the multiplexer 123, through the isolation unit (AND gate) 120a. In addition, since the save enable signal save_en is also at a logic high level, the clock signal CPU_CLK can be coupled to the clock input terminal of the storage unit (DFF_1) 122 through the isolation unit 120b and the AND gate (or the clock control cell) 121, thereby making the storage unit (DFF_1) 122 store the signal timer_en. Here, since the signal timer_en, that is the signal stored by the storage unit (DFF_0) 111b, is provided to be at the logic high level, the signal timer_en is kept at the logic high level, so the storage unit (DFF_1) 122 stores a signal at the logic high level.

At time t1, the selection signal sel_ret changes from a logic low level to a logic high level, causing the multiplexer 123 to select the other terminal (the “1” terminal) thereof as an output. That is, the value stored in the storage unit (DFF_1) 122 (logical high level) is selected to output as the signal timer_en_ret to the timer 124.

At time t2, the isolation signal iso_n changes from a logic high level to a logic low level, causing the outputs of the isolation units 120a and 120b are limited to a logic low level, so as to equivalently isolate or block the signal from the first circuit block 11 and prevent the unintended signal transmission to the second circuit block 12 (or the second power domain).

Finally, at time t3, the semiconductor device 10 cuts off the power supply of the first power domain VDD0, and enters the power-saving mode. As can be seen from the timing chart of FIG. 2, although the first power domain VDD0 is powered off, the signal timer_en_ret output to the timer 124 can still be kept at the setting value before entering the power-saving mode, that is, maintain at a logic high level.

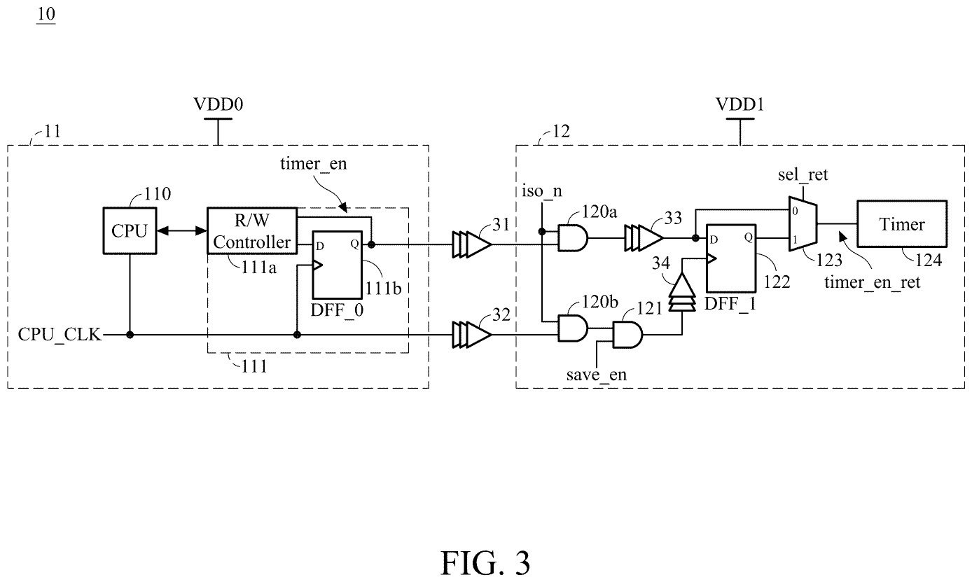

In practice, the circuits powered by the first power domain VDD0 and the circuit powered by the second power domain VDD1 may be arranged in different regions on a semiconductor device (or chip). The first power domain VDD0 and the second power domain VDD1 may be far apart from each other due to layout considerations and limitations. Therefore, when transmitting signals between the first power domain VDD0 and the second power domain VDD1, a certain number of buffer devices need to be additionally provided, such as the buffer devices 31 to 34 shown in FIG. 3. The buffer devices 33 and 34 arranged in the second power domain VDD1 will increase the power consumption of the semiconductor device 10 in the power-saving mode. The other parts of the semiconductor device 10 of FIG. 3 have the same structure and operation as those of FIG. 1, and thus will not be described again.

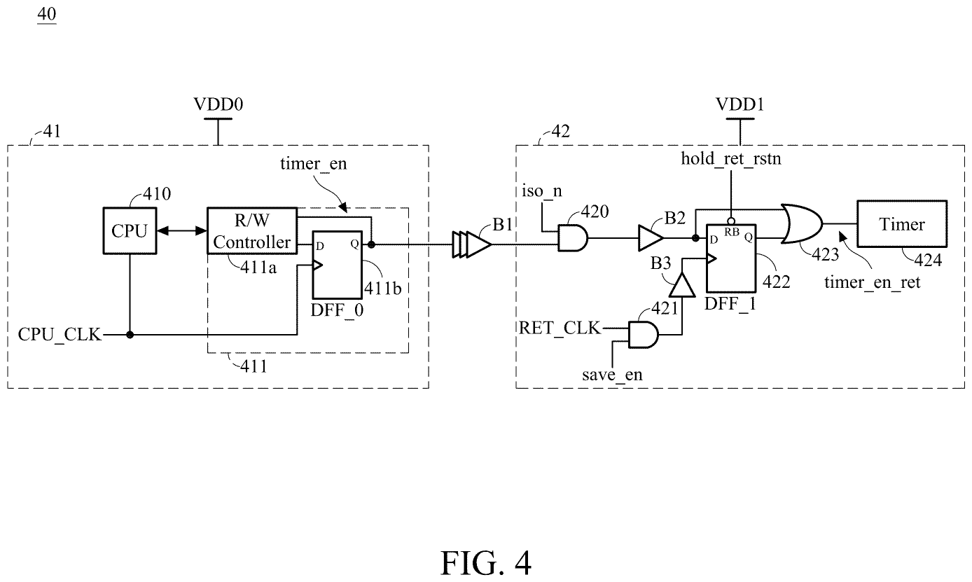

FIG. 4 is a structural diagram of a semiconductor device having a signal retain circuit according to one embodiment of the present invention.

In FIG. 4, the semiconductor device 40 includes a first circuit block 41 and a second circuit block 42. The first circuit block 41 has a first power domain, and the second circuit block 42 has a second power domain. That is, the power supply division on the semiconductor device 40 is at least arranged as: the first power domain supplying power to the whole of part of the first circuit block 41, and the second power domain supplying power to the whole or part of the second circuit block 42. Hereinafter, the first power domain and the second power domain are still labeled as VDD0 and VDD1, respectively.

Referring to FIG. 4, the first circuit block 41 includes a processor 410 and, for example but not limited to, a register controller 411 at least composed of a read/write controller (R/W controller) 411a and a storage unit 411b. The storage unit 411b may be a flip-flop or a latch of various types; here, for example, it is a D-type flip-flop (DFF_0). The processor 410 may be a central processing unit (CPU), a digital signal processor (DSP), a micro control unit (MCU), an arithmetic logic unit (ALU), or other device or circuit with program execution and computing capabilities. The processor 410 operates by receiving the CPU clock signal CPU_CLK generated by the first circuit block 41 or other clock generation circuits (not shown in FIG. 4) of the semiconductor device 41. The storage unit 411b receives the output of the read/write controller 411a and the CPU clock signal CPU_CLK, to store signals or data. It should be noted that in this embodiment, the CPU clock signal CPU_CLK is not input to the second circuit block 42.

Referring to FIG. 4, the second circuit block 42, that is the signal retain circuit, includes an isolation unit 420, an AND gate (or a clock gating cell) 421, a storage unit 422, an OR gate 423, and a timer 124. Here, the storage unit 422 may be a flip-flop or a latch of various types. Here, the storage unit 422, for example, is a D-type flip-flop DFF_1. It should be noted that in this embodiment (FIG. 4), the AND gate 421 is used as an example to receive the retain clock signal RET_CLK, but a clock gate cell may also be used to replace the AND gate 421. In addition, the clock gating cell, for example but not limited to, may be an integrated clock gating cell (ICG) to further eliminate glitches.

In the second circuit block 42, the isolation unit 420 is an AND gate in this embodiment. For the isolation unit 420, one input terminal is coupled to the isolation signal iso_n, and the other input terminal is coupled to the output terminal Q of the storage unit (DFF_0) 411b through the buffer device B1.

The output terminal of the isolation unit 420 is coupled to the input terminal (D) of the storage unit (DFF_1) 422 through the buffer device B2. The output terminal of the AND gate 421 is coupled to the clock input terminal of the storage unit (DFF_1) 422 through the buffer device B3. One input terminal of the AND gate 421 is coupled to the retain clock signal RET_CLK, and the other input terminal of the AND gate 421 is coupled to the save enable signal save_en.

One input terminal of the OR gate 423 is coupled to the input terminal of the storage unit (DFF_1) 422 and the output terminal of the isolation unit 420, and the other input terminal of the OR gate 423 is coupled to the output terminal of the storage unit (DFF_1) 422. The output terminal of the OR gate 423 outputs a signal timer_en_ret to the timer 424. From the connection of the OR gate 423, it can be known that the two input terminals of the OR gate 423 are respectively coupled to the output terminal of the storage unit (DFF_0) 411b and the output terminal of the storage unit (DFF_1) 422.

The operation of the first circuit block 41 of this embodiment is the same as the operation of the first circuit block 11 in FIG. 1, so the description thereof is omitted here.

Compared with the circuit structure of FIG. 1, in the second circuit block 42 of the present embodiment (FIG. 4), the retain clock signal RET_CLK is coupled to the clock input terminal of the storage unit (DFF_1) 422, instead of the CPU clock signal CPU_CLK. In addition, the reset terminal (RB) of the storage unit (DFF_1) 422 receives the signal hold_ret_rstn.

Compared with the circuit structure of FIG. 1, the important improvement of this embodiment (FIG. 4) is that the multiplexer 123 of FIG. 1 is removed, and the OR gate 423 is used to couple the output terminal of the storage unit (DFF_0) 411b to the input terminal of the storage unit (DFF_1) 422. It is particularly noted that the reason why the OR gate 422 can be used here is that the isolation unit (AND gate) 420 is limited to output the signal of logic low level by making the isolation signal iso_n be at a logic low level in the power-saving mode, such that, for the storage unit (DFF_0) 411b in the first power domain VDD0 being powered off, it is equivalent to forcing the output signal of the storage unit (DFF_0) 411b to be at a logic low level. If one of the input terminals of the OR gate 423 is at the logic low level, the state of its output logic will be determined by the input of the other input terminal of the OR gate 423. In circuit design, since the isolation unit 420 is added by the synthesis tool in the back-end process, the isolation unit 420 cannot be seen in the front-end process, so it is not easy for the designer to optimize the logic circuit, and the synthesis tool also cannot perform logic optimization.

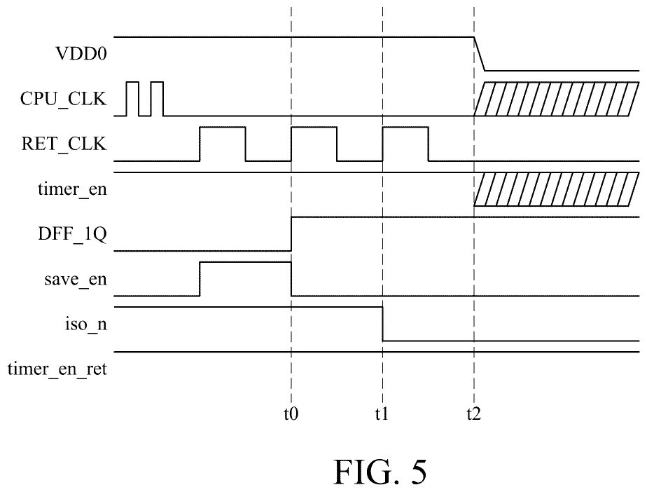

FIG. 5 is an operation timing chart of the semiconductor device of FIG. 4 when it enters a power-saving mode. Referring to FIG. 4 and FIG. 5, before time t0, the first circuit block 41 (or other clock circuits in the semiconductor device 40 (not shown)) stops outputting the CPU clock signal CPU_CLK. Next, the second circuit block 42 outputs the retain clock signal RET_CLK and the save enable signal save_en, which are coupled to the clock input terminal of the storage unit (DFF_1) 422 through the AND gate 421. Assume that the setting value stored in the storage unit (DFF_0) 411b is at a logic high level, so its output signal timer_en is at the logic high level.

At time t0, since the isolation signal iso_n is at the logic high level, the signal timer_en can be coupled to the input terminal of the storage unit (DFF_1) 422 and the input terminal of the OR gate 423 through the isolation unit (AND gate) 420. In addition, since the save enable signal save_en is also at the logic high level, the retain clock signal RET_CLK can be coupled to the clock input terminal of the storage unit (DFF_1) 422 through the AND gate 421, so that the storage unit (DFF_1) 422 stores the signal timer_en. The output signal of the output terminal (Q) of the storage unit (DFF_1) 422 is converted from an initial logic low level to a logic high level.

At time t1, the save enable signal save_en is kept at a logic low level, and the isolation signal iso_n changes from a logic high level to a logic low level, so that the output of the isolation unit (AND gate) 420 is limited to a low logic level. In this way, the signal from the first circuit block 41 is equivalently isolated or blocked to prevent unintended signals from being transmitted to the second circuit block 42 (or the second power domain VDD1).

At time t2, the semiconductor device 40 cuts off the power supply of the first power domain VDD0.

It should be noted that, compared to the semiconductor device 10 of FIG. 1, the semiconductor device 40 of the present embodiment has removed the multiplexer 123 and does not need to use the signal sel_ret for control, so the speed of entering the power-saving mode is much faster than the operation of the semiconductor 10 by one clock cycle.

In addition, according to this embodiment, since the save enable signal save_en, the isolation signal iso_n, the reset signal hold_ret_rstn and other related control signals in the second power domain VDD1 are controlled according to the retain clock signal RET_CLK; therefore, the CPU clock signal CPU_CLK is not required during the process of entering the power-saving mode. It should be noted that the frequency of the retain clock signal RET_CLK is lower than the frequency of the CPU clock signal CPU_CLK. When the semiconductor device 40 receives the instruction to enter the power-saving mode, the CPU clock signal CPU_CLK can be turned off first, such that most of the clock signals of the semiconductor device 40 will be turned off and thus most of the circuits of the semiconductor device 40 can be turned off, and whereby most of the circuits of the semiconductor device 40 can enter the power-saving mode faster and reduce power consumption thereof.

Furthermore, because the save enable signal save_en, the isolation signal iso_n, the reset signal hold_ret_rstn and other related control signals are controlled according to the retain clock RET_CLK, the size of the logic circuits using these signals (such as the storage unit (DFF_1) 422) will not need to be adjusted according to the frequency of the CPU clock signal CPU_CLK.

Microcontroller units (MCUs) are widely used in semiconductor devices. Therefore, the frequency of the CPU clock signal CPU_CLK used by the processors (such as CPU) can be set in a very wide range. The application more concerned about power consumption, the frequency of the CPU clock signal CPU_CLK is adjusted to a lower frequency, while the application more concerned about performance, the frequency of the CPU clock signal CPU_CLK is adjusted to a higher frequency. However, when designing the control timing of semiconductor devices or chips, the usage scenario at the highest frequency (or highest speed) must be considered. Therefore, in the structure of the semiconductor device 10 of FIG. 1, when the circuits in the first power domain VDD0 and the second power domain VDD1 share the CPU clock signal CPU_CLK, if the maximum speed of the processor of the semiconductor device or chip is close to the process limit of the product, then the storage unit (DFF_1) in the second power domain VDD1 will have to select components with larger area and more power consumption due to the high speed requirement. Furthermore, due to the high speed requirement, the number of buffer devices in the second power domain VDD1 may increase. In contrast, in the structure of the semiconductor device 40 of the present embodiment, the circuit of the second power domain VDD1 is controlled according to the retain clock signal RET_CLK, not according to the CPU clock signal CPU_CLK. Since the frequency of the retain clock signal RET_CLK does not need to be very fast, the storage unit (DFF_1) 422 can prioritize the most power-saving components. In addition, since there is no speed requirement, the number of buffer devices used is greatly reduced compared to the semiconductor device 10 of FIG. 3.

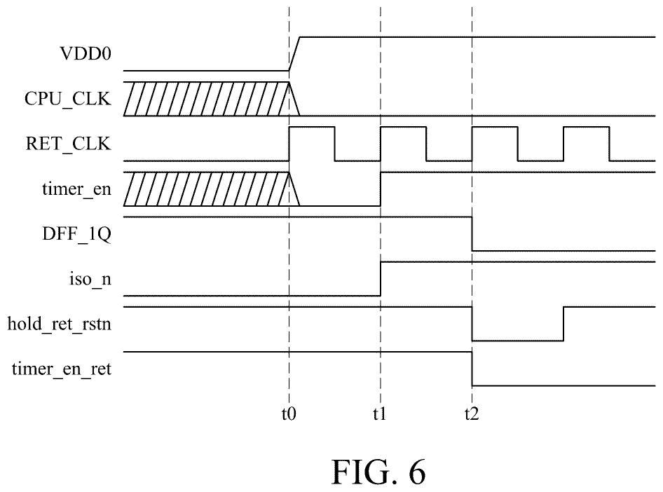

FIG. 6 is an operation timing chart of the semiconductor device of FIG. 4 when it leaves the power-saving mode. At time to in FIG. 6, the semiconductor device 40 first restores the power supply of the first power domain VDD0. Then, the setting value of the storage unit (DFF_0) 411b is restored to the preset value (logic low level). Next, at time t1, the second circuit block 42 changes the isolation signal iso_n from a logic low level to a logic high level to release the isolation of the output signal timer_en output from the storage unit (DFF_0), that is, the signal timer_en can be transmitted to the OR gate 423 and the storage unit (DFF_1) 423 of the second circuit block 42. At time t2, the second circuit block 42 sends the reset signal hold_ret_rstn to reset/clear the second storage unit (DFF_1) 423, so that its output signal timer_en_ret becomes a logic low level. Then, the first circuit block 41 outputs the CPU clock signal, and the second circuit block 42 stops outputting the retain clock signal RET_CLK.

It can be seen from the timing chart of FIG. 6 that after leaving the power-saving mode, the setting value of the storage unit (DFF_0) 411b will be restored to the preset (default) value, and the setting value (that is, the setting value stored in the storage unit (DFF_1) 423) originally used in the power mode cannot be used after leaving the power-saving mode. Therefore, a mechanism is needed to restore the value stored in the storage unit (DFF_1) 423 into the first power domain VDD0 after leaving the power-saving mode.

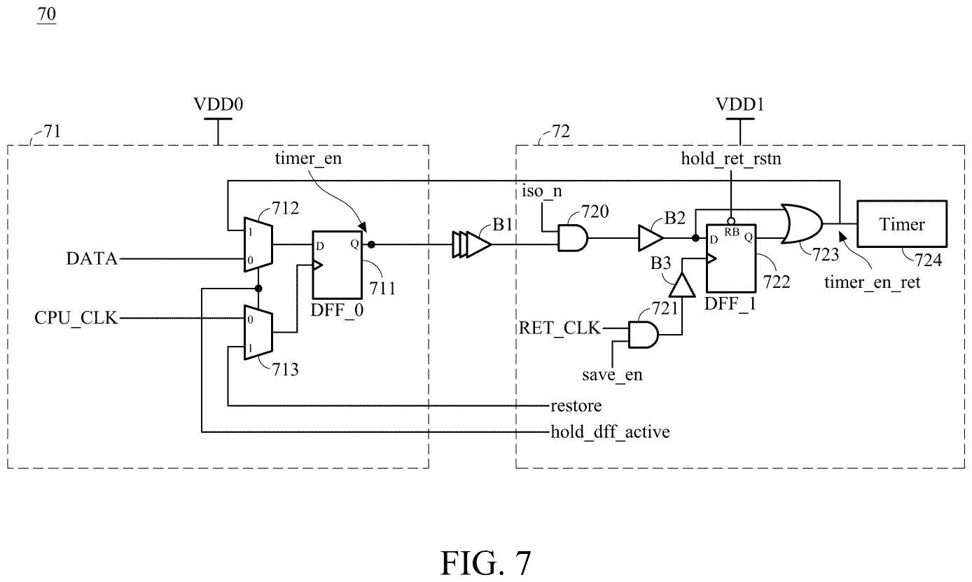

FIG. 7 is a structural diagram of a semiconductor device having a signal retain circuit and a signal restore circuit according to another embodiment of the present invention. The process and operation for the semiconductor device 70 of FIG. 7 to enter the power-saving mode are the same as that of the semiconductor device 40 of FIG. 4, and thus will not be further described.

In FIG. 7, the semiconductor device 70 includes a first circuit block 71 and a second circuit block 72. The first circuit 71 has a first power domain, and the second circuit 42 has a second power domain. That is, the power supply division on the semiconductor device 40 is at least arranged as: the first power domain supplying power to the whole of part of the first circuit block 41, and the second power domain supplying power to the whole or part of the second circuit block 42. Hereinafter, the first power domain and the second power domain are still labeled as VDD0 and VDD1, respectively.

Referring to FIG. 7, the second circuit block 72, that is the signal retain circuit, includes an isolation unit 720, an AND gate (or a clock gating cell) 721, a storage unit 722, an OR gate 723, and a timer 724. Here, the storage unit 722 may be a flip-flop or a latch of various types. Here, the storage unit 422, for example, is a D-type flip-flop DFF_1. In this embodiment, the second circuit block 72 has the same circuit structure and the same operation as the second circuit block 42 shown in FIG. 4, and therefore the details thereof will not be described in detail. However, in this embodiment, the second circuit block 72 outputs the restore signal (restore) and the select signal (hold_diff_active) to the first circuit block 71 when the semiconductor device 70 leaves the power-saving mode. It should be noted that in this embodiment (FIG. 7), the AND gate 721 is used as an example to receive the retain clock signal RET_CLK, but a clock gate cell may also be used to replace the AND gate 721. In addition, the clock gating cell, for example but not limited to, may be an integrated clock gating cell (ICG) to further eliminate glitches.

Referring to FIG. 7, similar to FIG. 4, the first circuit block 71 includes a processor, and a register controller which is composed of a read/write controller (R/W controller) and a storage unit. In addition, the first circuit block 71 further includes two multiplexers 712 and 713 are included. In this embodiment, only the multiplexer 712, the multiplexer 713, and the storage unit 711 are shown in FIG. 7, for brevity. The storage unit 711 may be a flip-flop or a latch of various types, and here, for example, it is a D-type flip-flop (DFF_0).

The selection control terminals of the multiplexers 712 and 713 are coupled to the selection signal hold_diff_active. A first input terminal of the multiplexer 712 is coupled to the output terminal of the OR gate 724, and a second input terminal of the multiplexer 712 is coupled to output data (DATA) of the read/write controller (not shown in FIG. 7). A first input terminal of the multiplexer 713 is coupled to the restore signal (restore), and a second input terminal of the multiplexer 713 is coupled to the CPU clock signal CPU_CLK. In addition, the output terminal of the multiplexer 712 is coupled to the input terminal (D) of the storage unit (DFF_0) 711, and the output terminal of the multiplexer 713 is coupled to the clock input terminal of the storage unit (DFF_0) 711.

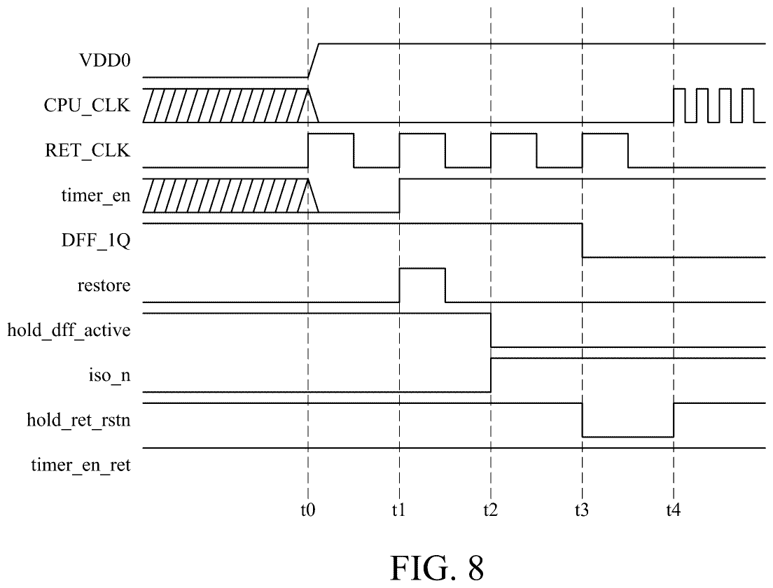

FIG. 8 is an example of an operation timing chart of the semiconductor device of FIG. 7 when it leaves the power-saving mode.

Referring to FIG. 8, at time t0, the semiconductor device 70 resumes the power supply of the first power domain VDD0. The output signal timer_en of the storage unit (DFF_0) 711 is a preset logic low level.

Since the selection signal hold_dff_active is kept at a logic high level, the multiplexer 712 outputs the output signal time_en_ret of the OR gate 723 to the input terminal (D) of the storage unit (DFF_0) 711, and the multiplexer 713 couples the first input terminal to the clock input terminal of the storage unit (DFF_0) 711.

Next, at time t1, the second circuit block 72 outputs the restore signal (restore) to the first input terminal of the multiplexer 713. The signal time_en_ret, that is the stored value of the storage unit (DFF_1) 722, is restored and stored in the storage unit (DFF_0) 711, through the driving of the restore signal (restore), so that the output timer_en of the storage unit (DFF_0) 711 is at a logic high level.

Next, at time t2, the second circuit block 72 changes the isolation signal iso_n from a logic low level to a logic high level to release the equivalent output restriction of the isolation unit 720 on the storage unit (DFF_0) 711. In addition, the second circuit block 72 also changes the selection signal hold_diff_active to a logic low level, so that the multiplexers 712 and 713 respectively couple their second input terminals to their output terminals, whereby the input terminal (D) of the (DFF_0) 711 can receive the data (DATA) output by the read/write controller (not shown) and the clock input terminal of the storage unit (DFF_0) 711 can receive the CPU clock signal CPU_CLK. At this point, the control of the storage unit (DFF_0) 711 is returned to the read/write controller (not shown).

Next, at time t3, the second circuit block 72 sends a reset signal hold_ret_rstn to reset the storage unit (DFF_1) 722 to reset the content of the storage unit (DFF_1) 722 to a logic low level. At time t4, the entire process of restoring the setting value has been completed. Finally, the second circuit block 72 stops outputting the retain clock signal RET_CLK, and the first circuit block 71 restarts outputting the CPU clock signal CPU_CLK.

Compared to FIG. 6, the output signal timer_en_ret of the OR gate 723 in FIG. 8 of this embodiment can be kept at a logic high level, which means that the setting value does not change as the semiconductor device 70 enters or leaves the power-saving mode, and such control manner is suitable for controlling the circuit that needs to continue working when entering or leaving the power-saving mode. On the other hand, the mechanism of this embodiment also reduces the processing time of the processor (not shown, such as the CPU) to read from and write to the storage unit (DFF_0) 711 again after leaving the power-saving mode.

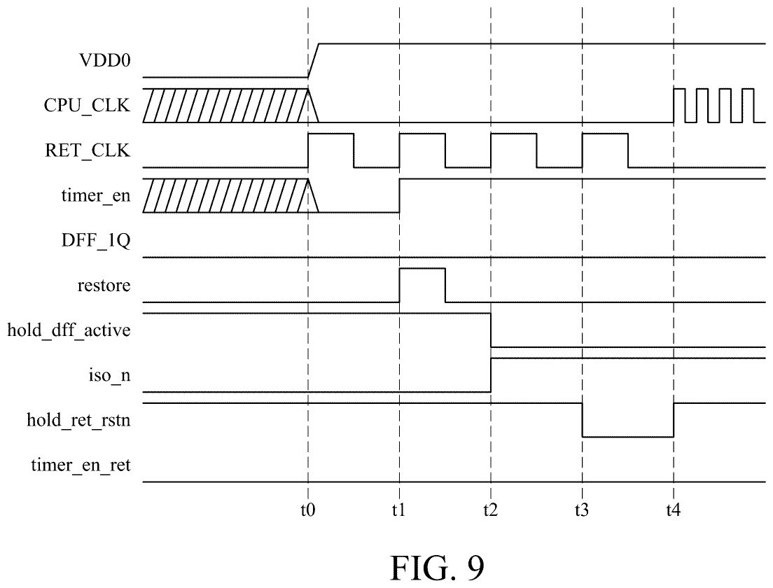

FIG. 9 is another example of an operation timing chart when the semiconductor device of FIG. 7 leaves the power-saving mode. In this example, the only difference from FIG. 8 is that the storage value of the storage unit (DFF_1) 722 in the power-saving mode is a logic low level, that is, the signal time_en_ret is also a logic low level. Similarly, it can be observed that the output signal timer_en_ret of the OR gate 723 in FIG. 8 can be kept at a logic low level, which means that the semiconductor device 70 in FIG. 7 can indeed operate correctly.

In addition, in FIG. 4 and FIG. 7, the semiconductor device, the first circuit block, and the second circuit block may have corresponding circuits (not shown) for outputting the aforementioned various control signals or logic signals.

It should be noted that some processes may provide a retention flip-flop. Although the retention flip-flop can achieve the purpose of maintaining the setting value, the output terminal (Q) of the retention flip-flop in the power-saving mode outputs no signal, so it cannot be used to control the circuits in non-power-off domains.

Based on the description of the above embodiments, the semiconductor device of the present invention has at least the following advantages.

(I) In the semiconductor device of the present invention, the CPU clock signal CPU_CLK and the retain clock signal RET_CLK are used in the first power domain and the second power domain which are independent of each other, respectively, and the frequency or speed of the retain clock signal RET_CLK is lower than the frequency of the CPU clock signal, and therefore smaller and more power-saving components can be used, and the amount of buffer devices used can be reduced. Furthermore, the present invention can use a low-speed storage unit (DFF_1).

(II) The second circuit block of the semiconductor device in FIG. 1 uses two isolation units and one multiplexer, while the present invention uses one isolation unit and one OR gate.

Taking a storage circuit with 287 bits as an example, if a voltage of 1.1 v is used for operation under a common process, according to the leakage current data of the component library, the power consumption of an OR gate is, for example, 0.021374964 nW, and the power consumption of one multiplexer is 0.040091908 Nw. Therefore, using the OR gate in the power-saving mode can save about 5.4 nW of power consumption.

In addition, the power consumption of a high-speed storage unit (DFF) is 0.11989983 nW, and the power consumption of a low-speed (DFF is 0.087509023 nW. Therefore, the present invention can save about 9.3 nW of power consumption in the DFF part.

As a result, the logic device of the semiconductor device using the structure of the present invention consumes about 620 nW in total, which can reduce the power consumption by about 2.3% compared with the architecture of FIG. 1. If the effect of reducing the number of buffer devices is added, the power consumption can be reduced even more.

(III) Compared with the retention flip-flop, the present invention is capable of continuously controlling the non-power-off domain when entering the power-saving mode, while the output terminal Q of the retention flip-flop cannot output signals after entering the power-saving mode.

(IV) In the semiconductor device of the present invention, in addition to using D-type flip-flop as a storage unit, it can also be replaced with a simpler latch to make the entire structure more power-saving.

Using the same process as described in (II) for analysis, the power consumption of one latch is 0.041198773 nW. Therefore, if a latch is used in the power-saving mode, about 22.6 nW can be saved, reducing power consumption by about 4.5%.

Although the present invention is disclosed as above with preferred embodiments, it is not intended to limit the scope of the present invention. Any person having ordinary skill in the technical field can make some changes without departing from the spirit and scope of the present invention. Therefore, the protection scope of the present invention shall be determined by the scope of the attached patent application.

What is claimed is:

1. A semiconductor device, comprising:
a first circuit block, configured to operate according to a first clock signal and at least have a first power domain and a first storage unit; and
a second circuit block, configured to at least have a second power domain and a second storage unit; an input terminal of the second storage unit being coupled to an output terminal of the first storage unit;
wherein when the semiconductor device enters a power-saving mode, it performs an enter procedure, in which:
the first circuit block stops outputting the first clock signal;
the second circuit block then outputs a second clock signal and a save enable signal which are coupled to the second storage unit;
the second storage unit stores the content of the first storage unit according to the save enable signal; and
the semiconductor device powers off the first power domain.

2. The semiconductor device as claimed in claim 1, wherein the second circuit block further comprises a logic OR gate;
one terminal of the logic OR gate is coupled to one input terminal of the second storage unit; and
the other terminal of the logic OR gate is coupled to the output terminal of the first storage unit.

3. The semiconductor device as claimed in claim 2, wherein the second circuit block further comprises a clock gate cell; input terminals of the clock gate cell receive the second clock signal and the save enable signal, and an output terminal of the clock gate cell is coupled to a clock input terminal of the second storage unit;
wherein when the storage signal is at a first logic level, the clock gate cell outputs the second clock signal, causing the second storage unit to store the content of the first storage unit.

4. The semiconductor device as claimed in claim 2, further comprising an isolation unit which is controlled by an isolation signal and is coupled to the output terminal of the first storage unit and the input terminal of the second storage unit;
wherein after the second storage unit has stored the content of the first storage unit, the second circuit block changes the isolation signal from a first logic level to a second logic level, such that the isolation unit restricts the output of the first storage unit to the second logic level to equivalently block the output of the first storage unit.

5. The semiconductor device as claimed in claim 4, wherein the isolation unit is a logic AND gate, which has one terminal coupled to the isolation signal, and the other terminal coupled to the output terminal of the first storage unit; and
the first logic level is a logic high level, and the second logic level is a logic low level.

6. The semiconductor device as claimed in claim 3, wherein the clock gate cell is an AND gate, and the first logic level is a logic high level.

7. The semiconductor device as claimed in claim 3, wherein the first storage unit and the second storage unit are flip-flops or latch circuits.

8. The semiconductor device as claimed in claim 2, wherein the first circuit block further comprises a first multiplexer and a second multiplexer;
a first input terminal of the first multiplexer is coupled to the output terminal of the logic OR gate, a second input terminal of the first multiplexer receives data, and an output terminal of the first multiplexer is coupled to the input terminal of the first storage unit;
a first input terminal of the second multiplexer receives a restore signal, a second input terminal of the second multiplexer receives the first clock signal, and an output terminal of the second multiplexer is coupled to the clock input terminal of the first storage unit; and
control terminals of the first multiplexer and the second multiplexer are coupled to a selection signal.

9. The semiconductor device as claimed in claim 8, wherein when the semiconductor device leaves the power-saving mode, it performs a leave procedure that includes the following steps:
the semiconductor device restores power to the first power domain;
the second circuit block sets the selection signal to the first logic level, causing the first multiplexer and the second multiplexer to select their respective first input terminals as outputs;
the second circuit block outputs the restore signal, which is input to the input clock terminal of the first storage unit through the second multiplexer, causing the first storage unit to store the content of the second storage unit; and
the second circuit block changes the logic level of the selection signal from the first logic level to the second logic level, causing the first multiplexer and the second multiplexer to select their respective second input terminal as outputs.

10. The semiconductor device as claimed in claim 9, wherein during the leave procedure, after the first storage unit has stored the content of the second storage unit, the leave procedure further includes the following steps:
the second circuit block resets the second storage unit;
the second circuit block stops outputting the second clock signal; and
the first circuit block outputs the first clock signal again.

11. The semiconductor device as claimed in claim 4, wherein when the semiconductor device leaves the power-saving mode, it performs the leave procedure that includes the following steps:
the semiconductor restores power to the first power domain;
the second circuit block changes the isolation signal from the second logic level to the first logic level, thereby releasing the blocking of the output from the first storage unit, by the isolation unit; and
the second circuit block resets the second storage unit.

12. The semiconductor device as claimed in claim 1, wherein a frequency of the second clock signal is lower than a frequency of the first clock signal.
